(19) United States
(12) Patent Application Publication
(10) Pub. No.: US 2007/0069373 A1
(43) Pub. Date: Mar. 29, 2007

(54) Device with surface cooling and method of making

(76) Inventor: Arti Prasad Roth, Cary, NC (US)

Correspondence Address: EDELL, SHAPIRO & FINNAN, LLC, 1901 RESEARCH BLVD., SUITE 400, ROCKVILLE, MD, 20850, US

(21) Appl. No.: 11/237,920

(22) Filed: Sep. 29, 2005

(51) Int. Cl. H01L 23/34

(52) U.S. Cl. 257/717

(57) ABSTRACT

An electrical or mechanical device which tends to heat up during operation, which bears on its surface a roughening coating comprised of thermally conductive material which aids in cooling the device.

### FIELD OF THE INVENTION

The invention relates to the cooling of electrical or mechanical devices by providing a surface roughening coating of thermally conductive material.

### BACKGROUND OF THE INVENTION

It is well known that many electrical and mechanical devices tend to heat up during operation, and that a rise in temperature may adversely affect performance. For example, in the case of electronic devices a rise in temperature of as little as 10° C. or less can have a significant negative effect. It is known to mount cooling fins made of metal on top of electronic devices and also to put a fan in the housing in which such devices are located. While approaches of this type help with cooling, they may not be enough.

### SUMMARY OF THE INVENTION

In accordance with the present invention, an electrical or mechanical device which tends to heat up during operation bears on its surface a surface roughening coating comprised of thermally conductive material, which aids in the cooling of the device.

### BRIEF DESCRIPTION OF THE DRAWINGS

The invention will be better understood by referring to the accompanying drawings wherein:

FIGS. 1 and 2 show prior art devices.

FIG. 3 depicts a first illustrative embodiment of the invention.

FIG. 4 depicts a second illustrative embodiment of the invention.

FIG. 5 depicts a third illustrative embodiment of the invention.

FIG. 6 depicts a fourth illustrative embodiment of the invention.

FIG. 7 depicts a fifth illustrative embodiment of the invention.

### DETAILED DESCRIPTION OF PREFERRED EMBODIMENTS

FIG. 1 depicts in representative form a device 2 which may be cooled in accordance with the present invention. The device may be any electrical or mechanical device which tends to heat up during operation. By way of non-limitative example, the device 2 may be a semiconductor integrated circuit device, in which case it may be located on a printed circuit board (PCB) such as PCB 4 shown in FIG. 1.

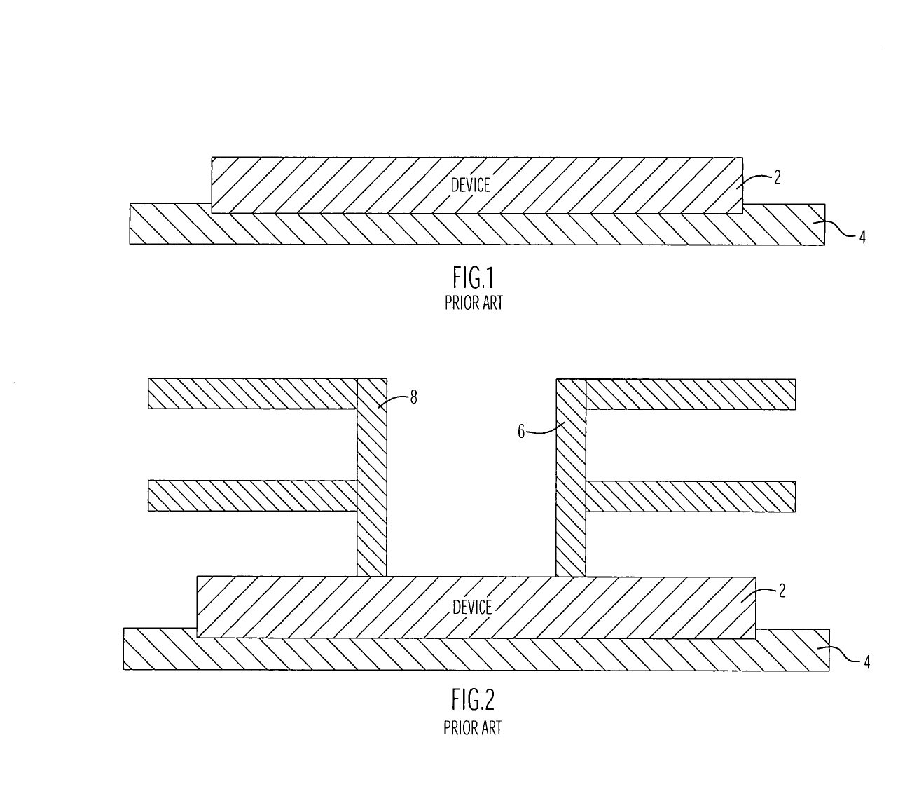

The heating of many electrical and mechanical devices during operation, including a semiconductor device such as is depicted in FIG. 1 can have a deleterious effect on performance. For example, if the temperature of some semiconductor devices (including dynamic random access memories (DRAMs) and DRAM modules) increases by 10° C. the adverse effect on performance can be significant. In the prior art, the rate of heat transfer away from such devices is increased by providing them with metal fins. In FIG. 2, the device 2 shown in FIG. 1 is depicted wherein cooling fins 6 and 8 are mounted on the device. Since the fins are metallic, they are thermally conductive and conduct heat away from the device faster than if they were not present. Additionally, the device shown in FIG. 2 may be located in a housing containing a fan which provides additional cooling effect. Although the prior art expedients of fins and fan help in cooling the device, they may not be effective enough to enable proper or optimum operation of the device.

In accordance with the present invention a roughening coating of thermally conductive material is applied to the surface of the device, or in the case of the embodiment of FIG. 2, to the surface of the cooling fins. The roughening coating may increase the surface area by a factor of many times. The increased surface area results in a greater rate of heat loss from the device to the surrounding air.

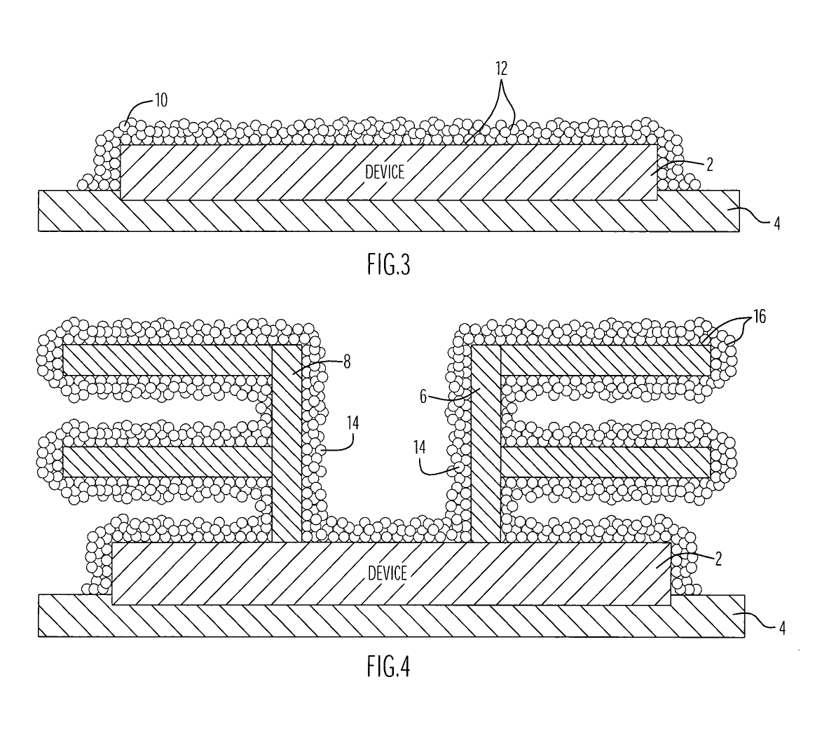

A first embodiment of the invention is shown in FIG. 3. In this embodiment, beads 10 of thermally conductive material are coated onto the surface of the device, resulting in an increase in surface area. The beads are preferably as small as can be practically realized to provide the greatest increase in surface area. For example, they may have a dimension of between about one micron and about one millimeter. The shape of the beads is preferably approximately spherical, but other round shapes including oval could also be used. The term “bead” as used herein means an element which is small compared to the size of the device being cooled and round. It may be solid or have an annular opening which extends entirely across a dimension.

The beads are made of thermally conductive material to provide suitable heat loss. The units of thermal conductivity are watts per meter-kelvin (W·m⁻¹·K⁻¹) and the term “thermally conductive” as used herein means having a thermal conductivity of at least about 200 W·m⁻¹·K⁻¹. Suitable materials of which the beads could be made include but are not limited to aluminum, copper, silver, gold, and diamond. The beads could be purchased from a supplier or could be custom made. For example, tiny copper balls could be cast in a mold.

The beads may be coated on the device with an epoxy or other suitable adhesive 12. Since the adhesive will form part of the coating in joining the-various beads together, it is preferably thermally conductive. Also, its coefficient of thermal expansion should be compatible with that of the device surface and with that of the beads to prevent dislocations from occurring when the device heats up. The respective materials for the beads and device surface may be selected so that a van der Waals attraction exists between individual ones of the beads themselves and between the beads and the device surface, in which case an adhesive may not be necessary. The van der Waal force is known to be a dipole induced attraction between molecules and atoms.

A further embodiment of the invention is shown in FIG. 4. In this embodiment, beads 14 are coated onto surfaces of cooling fins 6 and 8 with epoxy or other suitable adhesive 16. As in connection with FIG. 3, van der Waals materials may be used here also. It should be noted that it is not necessary to coat the entire surface of the device or fins, although it may be preferable to do so. The terminology “bears on its surface” as used herein means either on the entire surface or on part of the surface. Also, the term “device” means either the device itself or a module in which the device is housed.

A further embodiment of the invention is shown in FIG. 5. In this embodiment, a thermally conductive nanomaterial 20 is coated on device 2. The nanomaterial may be in the form of a powder. For example, a nanoceramic powder or one comprised of semiconductor nanocrystals may be used.

Because of the extremely small grains of which nanomaterials are made, they may result in an even greater increase in surface area than the beads shown in FIGS. 3 and 4. The thermal conductivity of such materials may be very high. For example, while diamond has the highest thermal conductivity of any naturally occurring substance, it has been reported that carbon nanotubes have a thermal conductivity which is twice that of diamond. A nanomaterial comprised of carbon nanotubes may be used, as may thermally conductive nanomaterials having spherical or other structures. Specific thermally conductive nanomaterials which may be used include but are not limited to metal powders such as those containing aluminum or copper nanoparticles.

Typically, the grain size in such materials is in the order of nanometers to less than a micron. The nanomaterial may be dissolved in a solution, and may be coated on the semiconductor device by evaporating the solution directly on the device in suitable cases. It also may be applied via a thin adhesive layer, for example a suitable epoxy, which does not dissolve or completely encompass the nanomaterial so as not to obviate surface roughness. Alternately, as discussed above, respective materials for nanomaterial coating and device surface having van der Waals attraction may be employed.

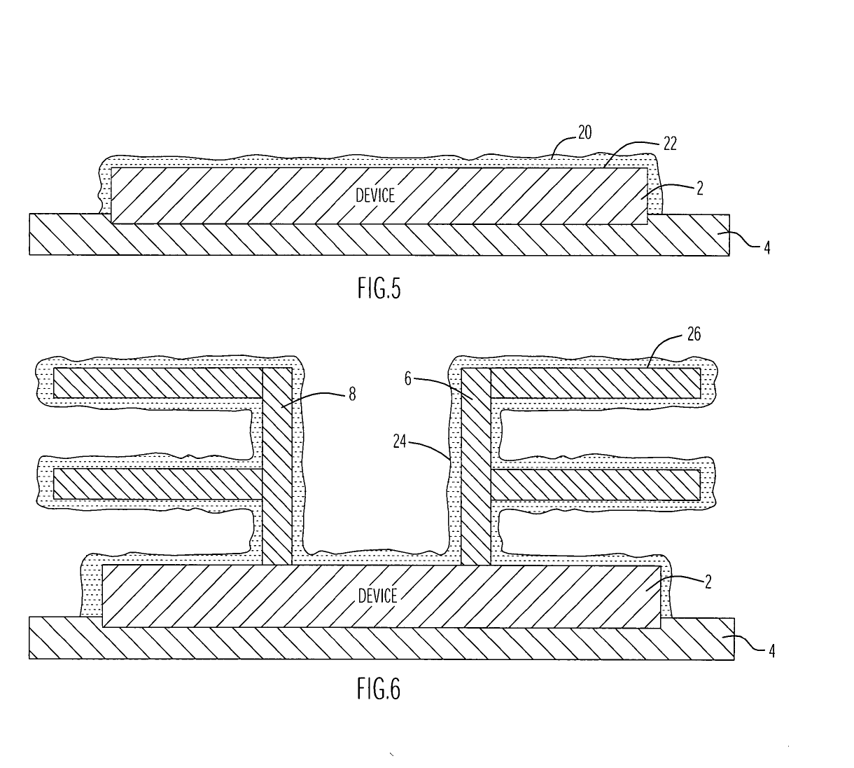

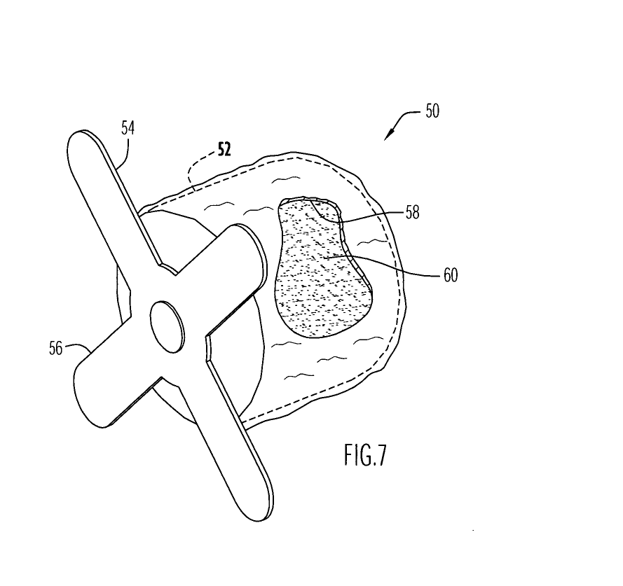

FIG. 6 shows a further embodiment of the invention where a nanomaterial 24 is applied on surfaces of fins 6 and 8 which are mounted on semiconductor device 2.

FIG. 7 shows a further embodiment of the invention where a nanomaterial is disposed on a mechanical device which in the example of the Figure is a microelectro-mechanical system (MEMS) fan. MEMS is a miniaturization technology wherein devices of extremely small dimension (order of microns) are fabricated. Referring to the Figure, fan 50 is comprised of motor housing 52 and blades 54 and 56. The motor housing 52 tends to heat up during operation, and in accordance with the invention is coated with nanomaterial 58 to aid in cooling. The nanomaterial 58 may be applied as described above.

It should be emphasized that while the invention has been described in connection with particular electrical and mechanical devices, it is broadly applicable to any electrical or mechanical device which has a tendency to heat up during operation. Such devices include but are not limited to electronic devices, motorized devices, optical elements and devices, and lamps and lamp modules.

The invention also includes a method of making a device having improved cooling comprising the steps of providing an electrical or mechanical device, providing a surface roughening medium of thermally conductive material, and coating the surface roughening medium on a surface of the electrical or mechanical device. As mentioned above, the coating may be performed with an epoxy or other adhesive, or with van der Waals materials.

It should be understood that while the invention has been described in detail and with reference to specific embodiments thereof, it will be apparent to one skilled in the art that various changes and modifications can be made therein without departing from the spirit and scope thereof. Accordingly, it is intended that such modifications and variations of the invention be covered provided they come within the scope of the appended claims and their equivalents.

I claim:

1. An electrical or mechanical device which tends to heat up during operation, which bears on its surface a roughening coating comprised of thermally conductive material which aids in cooling the device.

2. The device of claim 1 wherein the roughening coating is comprised of a plurality of beads of said thermally conductive material.

3. The device of claim 2 wherein the roughening coating is adhered to the surface with an epoxy.

4. The device of claim 1 wherein the roughening coating is comprised of a nanomaterial.

5. The device of claim 4 wherein the roughening coating is adhered to the surface with an epoxy.

6. An electrical or mechanical device which tends to heat up during operation, which bears on its surface a roughening coating comprised of a plurality of beads of thermally conductive material, which aids in cooling the device.

7. The device of claim 6 wherein the roughening coating is adhered to the surface with an epoxy.

8. The device of claim 6 wherein the roughening coating is adhered to the surface by van der Waals attraction.

9. The device of claim 6 wherein the beads are approximately spherical in shape.

10. The device of claim 6 wherein the device is an electrical device having cooling fins and wherein the roughening coating is disposed on a surface of the cooling fins.

11. An electrical or mechanical device which tends to heat up during operation, which bears on its surface a roughening coating comprised of a thermally conductive nanomaterial, which aids in cooling the device.

12. The device of claim 1 1 wherein the nanomaterial is in the form of a powder.

13. The device of claim 12 wherein the nanomaterial is adhered to the surface with an adhesive.

14. The device of claim 12 wherein the nanomaterial is adhered to the surface by van der Waals attraction.

15. The device of claim 11 wherein the device is an electrical device having cooling fins and wherein the roughening coating is disposed on a surface of the cooling fins.

16. A device comprising:
electrical or mechanical means which tends to heat up during operation; and
surface roughening means disposed on a surface of the electrical or mechanical means for increasing the rate of heat flow from said surface.

17. The device of claim 16 wherein the surface roughening means comprises a plurality of beads of thermally conductive material.

18. The device of claim 16 wherein the surface roughening means comprises a thermally conductive nanomaterial.

19. The device of claim 16 wherein the electrical or mechanical means comprises an electrical semiconductor integrated circuit unit.

20. The device of claim 19 wherein the integrated circuit unit has cooling fins and wherein the surface roughening means is coated on a surface of the cooling fins.

21. A method of making a device having improved cooling comprising the steps of:
providing an electrical or mechanical device;
providing a surface roughening medium of thermally conductive material; and
coating the surface roughening medium on a surface of the electrical or mechanical device.

22. The method of claim 21 wherein the surface roughening medium comprises a plurality of beads of thermally conductive material.

23. The method of claim 22 wherein the coating is performed with an epoxy.

24. The method of claim 21 wherein the surface roughening medium comprises a thermally conductive nanomaterial.

25. The method of claim 24 wherein the coating is performed with an adhesive.

26. The method of claim 21, wherein the coating is performed by adhering the thermally conductive material to the surface by van der Waals attraction.
